(19) United States
(12) Patent Application Publication
(10) Pub. No.: US 2012/0000888 A1
(43) Pub. Date: Jan. 5, 2012

(54) METHODS AND APPARATUS FOR RADIO FREQUENCY (RF) PLASMA PROCESSING

(75) Inventors: KATSUMASA KAWASAKI, San Jose, CA (US); BRYAN LIAO, Forest Hills, NY (US)

(73) Assignee: APPLIED MATERIALS, INC., Santa Clara, CA (US)

(21) Appl. No.: 13/014,807

(22) Filed: Jan. 27, 2011

Related U.S. Application Data
(60) Provisional application No. 61/360,144, filed on Jun. 30, 2010.

(51) Int. Cl. H01L 21/3065; H03H 7/40

(52) U.S. Cl. 216/67; 333/17.3

(57) ABSTRACT

Methods and apparatus for minimizing reflected radio frequency (RF) energy are provided herein. In some embodiments, an apparatus may include a first RF energy source having frequency tuning to provide a first RF energy, a first matching network coupled to the first RF energy source, one or more sensors to provide first data corresponding to a first magnitude and a first phase of a first impedance of the first RF energy, wherein the first magnitude is equal a first resistance defined as a first voltage divided by a first current and the first phase is equal to a first phase difference between the first voltage and the first current, and a controller adapted to control a first value of a first variable element of the first matching network based upon the first magnitude and to control a first frequency provided by the first RF energy source based upon the first phase.

### CROSS-REFERENCE TO RELATED APPLICATIONS

This application claims benefit of U.S. provisional patent application Ser. No. 61/360,144, filed Jun. 30, 2010, which is herein incorporated by reference.

### FIELD

Embodiments of the present invention generally relate to plasma processing equipment.

### BACKGROUND

In conventional radio frequency (RF) plasma processing, such as is used during stages of fabrication of many semiconductor devices, RF energy, which may be generated in continuous or pulsed wave modes, may be provided to a substrate process chamber via an RF energy source. Due to mismatches between the impedance of the RF energy source and the plasma formed in the process chamber, RF energy is reflected back to the RF energy source, resulting in inefficient use of the RF energy and wasting energy, potential damage to the process chamber or RF energy source, and potential inconsistency/non-repeatability issues with respect to substrate processing. As such, the RF energy is often coupled to the plasma in the process chamber through a fixed or tunable matching network that operates to minimize the reflected RF energy by more closely matching the impedance of the plasma to the impedance of the RF energy source. In some embodiments, the RF energy source may also be capable of frequency tuning, or adjusting the frequency of the RF energy provided by the RF energy source, in order to assist in impedance matching.

However, the inventors have discovered that conventional methods and apparatus for minimizing reflected energy are less than perfect. For example, the RF energy source has a tuning algorithm that allows the RF frequency to be modified based upon the reflected energy. However, such tuning algorithms may result in stopping the tuning at a local minima rather than at the absolute minimum reflected energy. In addition, the matching network and the RF energy source are typically independently tuned, resulting in inefficient tuning where the RF energy source and the matching network may compete against each other in an attempt to minimize the reflected RF energy.

Accordingly, the inventors have provided improved methods and apparatus for RF plasma processing.

### SUMMARY

Methods and apparatus for minimizing reflected radio frequency (RF) energy are provided herein. In some embodiments, an apparatus may include a first RF energy source having frequency tuning to provide a first RF energy, a first matching network coupled to the first RF energy source, one or more sensors to provide first data corresponding to a first magnitude and a first phase of a first impedance of the first RF energy, and a controller to control a first value of a first variable element of the first matching network based upon the first magnitude and to control a first frequency provided by the first RF energy source based upon the first phase.

In some embodiments, the apparatus may further include a second RF energy source having frequency tuning to provide a second RF energy; and a second matching network coupled to second RF energy source, wherein the one or more sensors further provide second data corresponding to a second magnitude and a second phase of a second impedance of the second RF energy, wherein the controller further controls a second value of a second variable element of the second matching network based upon the second magnitude and controls a second frequency provided by the second RF energy source based upon the second phase.

In some embodiments, the apparatus may further include a second RF energy source having frequency tuning to provide a second RF energy coupled to the electrode via the first matching network, wherein the first matching network further comprises a second variable element, wherein the one or more sensors further provides second data corresponding to a second magnitude and a second phase of a second impedance of the second RF energy, wherein the controller further controls a second value of the second variable element of the first matching network based upon the second magnitude and controls a second frequency provided by the second RF energy source based upon the second phase.

In some embodiments, a method for tuning a system operating a plasma process using a first RF energy source capable of frequency tuning and coupled to a process chamber via a first matching network may include providing a first RF energy at a first frequency to the process chamber via the first RF energy source, measuring a first voltage and a first current, determining a first magnitude and a first phase of a first impedance of the first RF energy, tuning a first variable element of the first matching network to adjust the first magnitude if the first magnitude is not within a desired tolerance level of a desired value and tuning the first frequency of the first RF energy source to adjust the first phase if a first phase difference between the first voltage and the first current is not within a desired tolerance level of zero.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic view of a processing system in accordance with some embodiments of the present invention

FIG. 2 depicts a schematic diagram of a semiconductor wafer processing system in accordance with some embodiments of the present invention.

FIG. 3 depicts an exemplary match circuit suitable for use in connection with some embodiments of the present invention.

FIG. 4 depicts an exemplary match circuit suitable for use in connection with some embodiments of the present invention.

FIG. 5 depicts an exemplary match circuit suitable for use in connection with some embodiments of the present invention.

FIG. 6 depicts a flow chart of a method for tuning a system operating a plasma process in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Methods and apparatus for radio frequency (RF) plasma processing are provided herein. In particular, methods and apparatus for minimizing reflected RF energy during such plasma processing are disclosed herein. The inventive methods and apparatus advantageously provide a stable minimized reflected RF energy state in a plasma process. In some embodiments, the minimized reflected RF energy may be provided by finding a global minimum in reflected RF energy through shared communication between the matching network and the RF energy source. In some embodiments, the minimized reflected RF energy may be provided by adjusting different aspects (e.g., magnitude and phase) of impedance of RF energy provided by the RF energy source. As used herein, the phrase “impedance of the RF energy” refers to the impedance of the circuit along which the RF energy is travelling. In some embodiments, control of the matching network and the RF energy source may be provided by a common controller to avoid competition between the conventionally independent tuning algorithms of the matching network and the RF energy source. The inventive methods and apparatus advantageously provide reduced tuning time and/or prevent damage due to reflected RF power from impedance mismatch, thus limiting prolonged tool servicing between processes and reducing costs by eliminating the need for more sophisticated match network elements, such phase capacitors, required to achieve tuning using conventional methods.

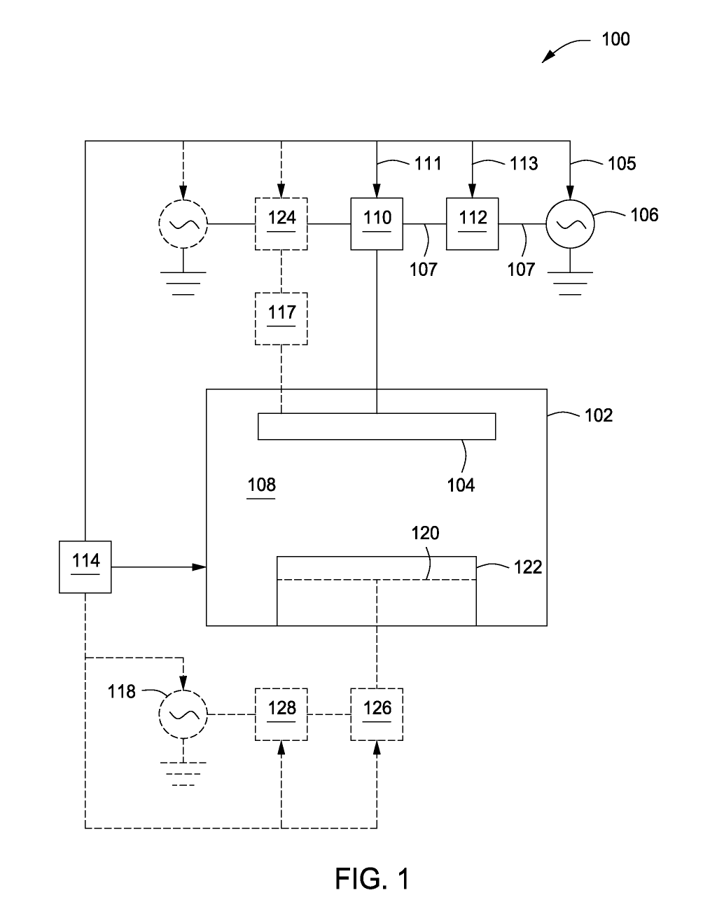

FIG. 1 depicts a schematic view of a processing system in accordance with some embodiments of the present invention. The processing system 100 may generally include a process chamber 102 having an electrode 104 for providing a first RF energy from a first RF energy source 106 having frequency tuning into a processing volume 108 of the process chamber 102. The first RF energy source 106 may be coupled to the electrode 104 via a first matching network 110. Although the electrode 104 is shown disposed in an upper portion of the process chamber 102, the electrode 104 may be disposed in other suitable locations as well, for example, in a substrate support disposed in the process chamber, or in locations disposed outside of the process chamber for inductive coupling of RF energy to the plasma in the process chamber. Exemplary process chambers may include the DPS®, ENABLER®, ADVANTEDGE™, or other process chambers, available from Applied Materials, Inc. of Santa Clara, Calif. Other suitable process chambers may similarly be used.

The first RF energy source 106 is configured for frequency tuning (e.g., the source may be able to vary frequency within about +/−10 percent in response to a sensed reflected energy measurement in order to minimize reflected energy). Such frequency tuning may require up to about 200 milliseconds or greater than about 200 milliseconds to minimize the reflected energy from a plasma. The RF energy source may be operable in a continuous wave (CW) or pulsed mode. When in pulse mode, the RF energy source may be pulsed at a pulse frequency of up to about 100 kHz, or in some embodiments, between about 100 Hz to about 100 kHz. The RF energy source may be operated at a duty cycle (e.g., the percentage of on time during the total of on time and off time in a given cycle) of, for example, between about 10% and about 90%.

The system 100 may include one or more first sensors 112 to provide first data corresponding to a first magnitude and a first phase of a first impedance of the first RF energy provided by the first RF energy source 106. The first data may include, for example, a first voltage and a first current. The first voltage and first current may be used to determine the first magnitude and the first phase of the first impedance. As used herein, the magnitude of the impedance is equal to (resistance²+reactance²)^{0.5}, where the resistance is the real part of the impedance of the circuit along which the RF energy is travelling and the reactance is the imaginary part of the impedance of the circuit along which the RF energy is travelling.

The one or more sensors may any suitable sensor devices for measuring voltage and current, for example, including inductors, resistors, or other suitable devices to measure voltage and/or current. Exemplary sensors for measuring voltage and current may be available from any of MKS Instruments of Andover, Mass., Bird Technologies Group of Solon, Ohio, Advanced Energy Industries of Fort Collins, Colo., ADTEC Technologies Inc. of Fremont, Calif., or Daihen Advanced Component Inc. of Santa Clara, Calif. Further, exemplary sensors can be found in U.S. Pat. No. 7,548,741, entitled “Dual logarithmic amplifier phase-magnitude detector” filed Aug. 29, 2006, or U.S. Pat. No. 6,661,324, entitled “Voltage and current sensor” filed Aug. 1, 2002, which are incorporated herein by reference.

The one or more first sensors 112 may be coupled to the system 100, for example at an input of the first matching network 110, between the first matching network 110 and the first RF energy source 106, such as on a transmission line 107 coupling the first RF energy source 106 to an input of the first matching network 110 (such as a coaxial cable), or at any location suitable for measuring the first phase and the first magnitude of the first impedance of the first RF energy. For example, in embodiments where only one RF energy source is coupled to the electrode 104, the one or more first sensors 112 may be coupled along a transmission line between the output of the first matching network 110 and the electrode 104. Further, in some embodiments, the one or more first sensors 112 may be incorporated into the RF energy source 106.

In some embodiments, the one or more first sensors 112 may be part of the first matching network 110. By putting the one or more first sensors 112 (e.g., a voltage/current detector) in the matching network 110, one of the first phase or first magnitude signals can be assigned to the tunable element of the matching network 110 (for example, a load capacitor) and the tunable element can be automatically tuned to the null point, or some other desired point, of that signal (e.g., zero for the first phase and, in some embodiments, about 50 Ohms for the first magnitude) via a controller. The other signal of the first phase or first magnitude can be assigned to control the frequency of the first RF energy source 106, which may be automatically tuned to the null point, or other desired point of that signal via the controller. When both desired points are met using this feedback control at the same time, the impedance matching will be perfect (e.g., as good as possible) and the reflected power will be close to zero. Typically, in a perfect impedance match the reflected power is exactly zero, however, taking into account slight error in measure, non-linearities in the plasma, losses in transmission lines/cable and/or the match network, the reflected power may be close to zero, rather than exactly zero. In some embodiments, the first matching network 110 and the first RF energy source 106 may be coupled, for example, via a user interface (such as serial communication) directly and the first matching network 110 can determine the suitable frequency for the RF generator and can send a command to the first RF energy source 106 to set the desired frequency of operation. Alternatively, in some embodiments, the first matching network 110 and the first RF energy source 106 may be coupled indirectly via the semiconductor equipment (for example, via a controller of the processing system 100).

Conventional matching networks and RF energy sources typically each contain control algorithms used for tuning the respective systems that are independent. Accordingly, each algorithm operates independently with respect to the other, which may cause a significant competition between the two tuning algorithms. Such competition, therefore, might cause system instabilities. Accordingly, in some embodiments of the present invention, a single controller (e.g., controller 114) is provided for controlling the first matching network 110 and the first RF energy source 106.

For example, the system 100 further includes a controller 114 to control the first RF energy source 106 and the first matching network 110. The controller 114 comprises a central processing unit (CPU), a memory and support circuits. The controller 114 is coupled to various components of the system 100 to facilitate control of the process. The controller 114 regulates and monitors processing in the chamber via interfaces that can be broadly described as analog, digital, wire, wireless, optical, and fiber optic interfaces. To facilitate control of the chamber as described below, the CPU may be one of any form of general purpose computer processor that can be used in an industrial setting for controlling various chambers and subprocessors. The memory is coupled to the CPU. The memory, or a computer readable medium, may be one or more readily available memory devices such as random access memory, read only memory, floppy disk, hard disk, or any other form of digital storage, either local or remote. The support circuits are coupled to the CPU for supporting the processor in a conventional manner. These circuits include cache, power supplies, clock circuits, input/output circuitry and related subsystems, and the like.

Etching, or other, process instructions are generally stored in the memory as a software routine typically known as a recipe. The software routine may also be stored and/or executed by a second CPU (not shown) that is remotely located from the hardware being controlled by the CPU of the controller 114. The software routine, when executed by CPU, transforms the general purpose computer into a specific purpose computer (controller) 114 that controls the system operation such as controlling the RF energy source(s) and the matching network(s) to minimize reflected RF energy during plasma processing. Although the process of the present invention can be implemented as a software routine, some of the method steps that are disclosed therein may be performed in hardware as well as by the software controller. As such, embodiments of the invention may be implemented in software as executed upon a computer system, and hardware as an application specific integrated circuit or other type of hardware implementation, or a combination of software and hardware.

The controller 114 may be in direct or indirect communication with each of the first matching network 110, the one or more sensors 112 and the first RF energy source 106. The controller 114 may control the frequency provided by the first RF energy source 106 and the value of a tunable element, or variable element of the first matching network 110 in response to data provided by the one or more sensors 112 representing the phase and magnitude of the first reflected RF energy. Additionally, the controller 114 may be further utilized to control other components of the system 100, such as the process chamber 102 or components thereof that require control. For example, the controller may further control a second RF energy source 116 coupled to the electrode 104 via the first matching network 110 or a second matching network 117 and/or a third RF energy source 118 coupled to a electrode 120 disposed in a substrate support 122 within the process chamber 102.

The controller 114 may have inputs (not shown) for receiving voltage and current signals from the one or more first sensors 112 via a signal line 113 and outputs for sending instructions to adjust one or more variable elements of the first matching network 110 and the first RF energy source 106 via communication lines 111 and 105 respectively coupled to the first matching network 110 and the first RF energy source 106. In some embodiments, a separate input may be provided for each voltage and current signal. Further, when multiple RF energy sources, matching networks and sensors are controlled by a single controller, such as shown optionally in FIG. 1 and discussed below, the controller 114 may further include additional inputs and outputs necessary to control additional RF energy sources, matching networks, and sensors.

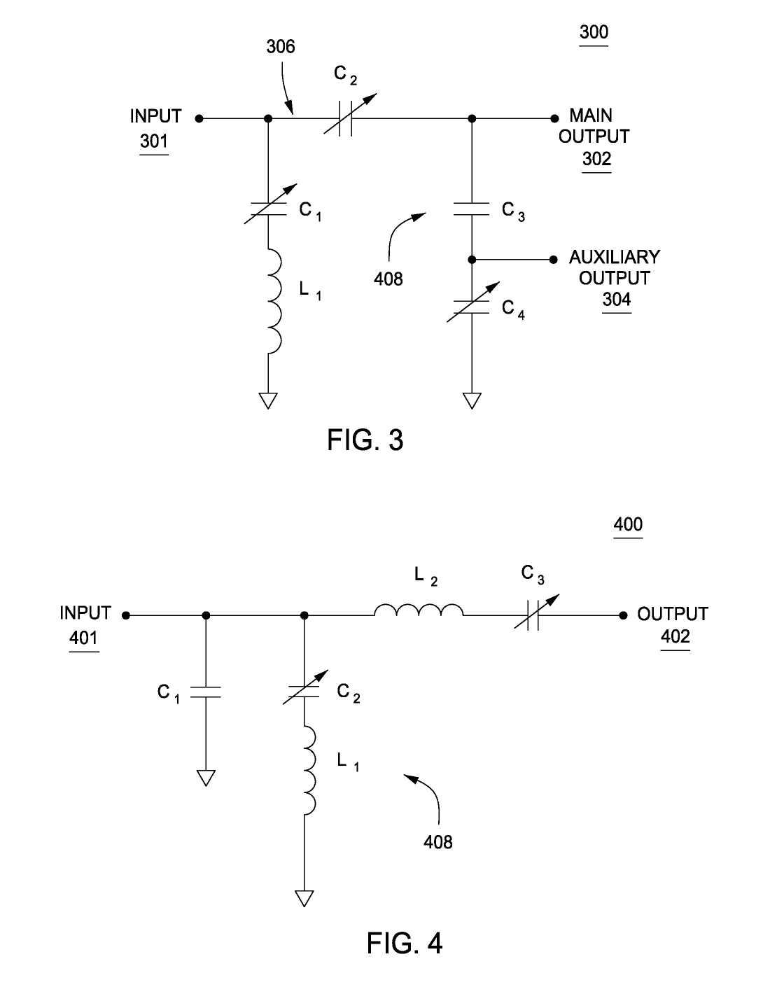

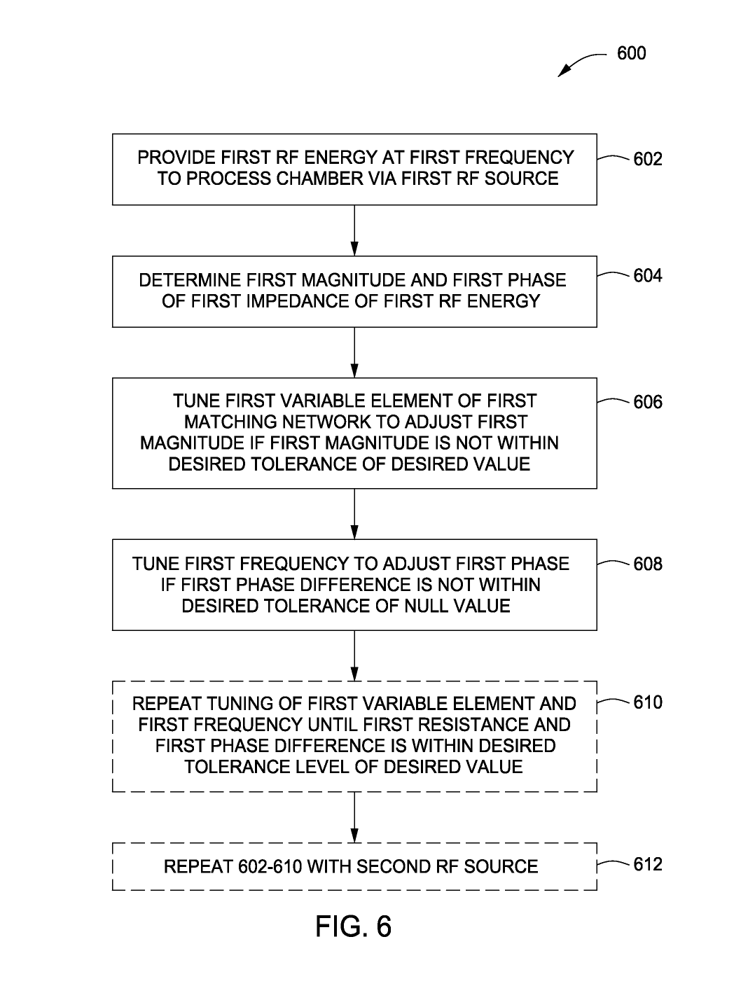

For example, the controller 114 may control a first value of one or more first variable tuning elements of the first matching network 110 (such as a variable capacitor C₁ or C₂ of a matching network 300 shown in FIG. 3, discussed below) based upon the first magnitude of the first reflected RF energy. The controller 114 may adjust the value of the variable tuning elements of the first matching network 110 in order to adjust the first magnitude of the first impedance to a desired value or to some value within a specified tolerance of the desired value as discussed below with respect to the method 600 described in FIG. 6. For example, the desired value may vary depending on the types of equipment used, such as gauge of wires in coaxial cables or transmission lines, which may define a characteristic impedance of those lines for a particular application. For example, in some embodiments of the present invention, the desired value of the first magnitude is about 50 Ohms (e.g., a common impedance of components used in the semiconductor industry), although any desired value may be used to correspond with a characteristic impedance of the equipment in a particular application.

The controller 114 may further control a first frequency provided by the first RF energy source 106 based upon the first phase of the first impedance. The controller 114 may adjust the frequency of the first RF energy source 106 in order to reduce the first phase difference between the first voltage and the first current to zero, or to some value within a desired tolerance of zero, as discussed below with respect to the method 600 described in FIG. 6.

In some embodiments, the algorithms used for tuning the first matching network 110 and the first frequency of the first RF energy source 106 may both be controlled based on the first magnitude and the first phase of the first impedance of the first RF energy as measured by the one or more first sensors 112. Embodiments of a method 600 by which the reflected RF energy is minimized in any of the embodiments of the process system as depicted in FIGS. 1-5 is discussed further below.

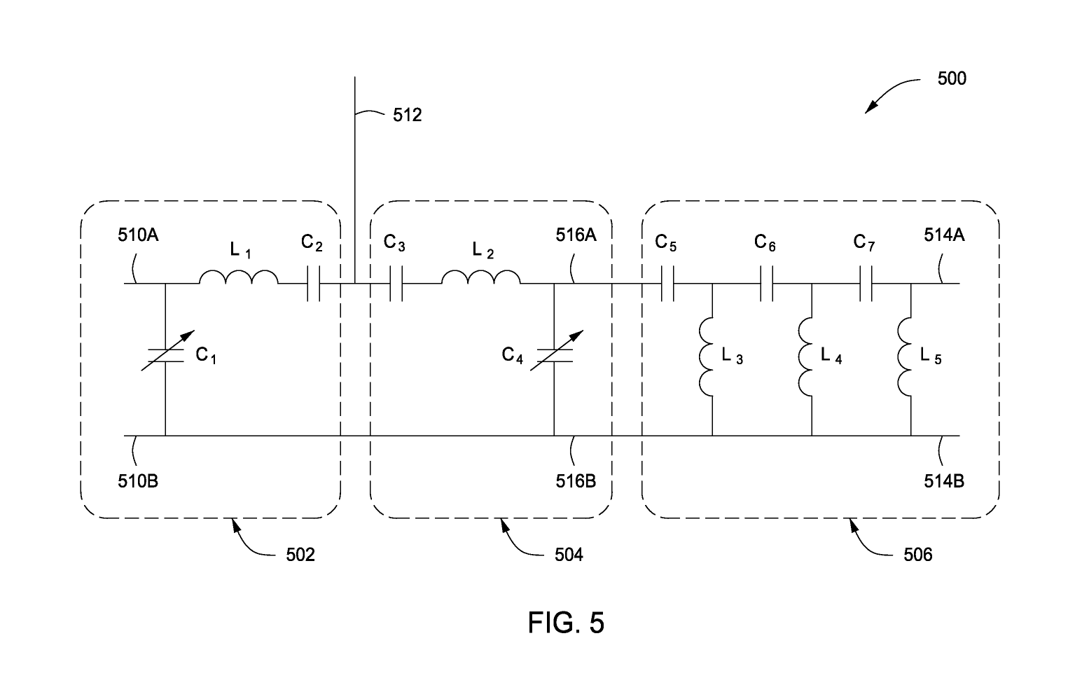

As illustrated in FIG. 1, one or more RF energy sources may be coupled to an electrode via one or more matching networks. For example, as discussed above, the first RF energy source 106 (also referred to as an RF generator) may be coupled to the electrode 104 via the first matching network 110. For example, in such a configuration, the first matching network 110 may be substantially similar to the matching network 300 discussed below and depicted in FIG. 3, for example using the main output 302 when the electrode 104 is a single piece, or using both the main output 302 and auxiliary output 304 when the electrode 104 is a pair of coils. Further, any suitable matching network having a variable element and for coupling an RF energy source may be used, for example, such as a matching network configured similarly to the sub-circuit 502 of the matching network 500 depicted in FIG. 5 and discussed below.

In some embodiments, a second RF energy source 116 having frequency tuning to provide a second RF energy may be coupled to the electrode 104 via the second matching network 117. The second RF energy source 116 may be similar to the first RF energy source 106 with the exception that the second RF energy source 116 may provide RF energy at a different frequency than the first RF energy source 106. One or more second sensors 124 may provide second data corresponding to a second magnitude and a second phase of a second impedance of the second RF energy. The second data may include, for example, a second voltage and a second current. The second voltage and second current may be used to determine the second magnitude and the second phase of the second impedance. The controller 114 may further control a second value of a second variable element of the second matching network 117 based upon the second magnitude and further control a second frequency of the second RF energy source 116 based upon the second phase.

Alternatively, the second RF energy source 116 may be coupled to the electrode 104 via the first matching network 110 (in combination with the first RF energy source 106). In such embodiments, the first matching network 110 may be substantially similar to the multi-frequency matching network 500 discussed below and depicted in FIG. 5. For example, the first matching network 110 in this alternative embodiment may include the first variable element corresponding to the first RF energy source 106 as discussed above and a second variable element corresponding to the second RF energy source 116. The one or more sensors 124 may provide second data corresponding to the second magnitude and the second phase of the second impedance of the second RF energy, as illustrated in FIG. 1. Alternatively, the one or more sensors 112, 124 may be a single sensor which provides both the first and second data (not shown). The controller 114 may control the second value of the second variable element of the first matching network 110 based upon the second magnitude and control the second frequency provided by the second RF energy source 116 based upon the second phase.

Additional embodiments of the system 100 may include the third RF energy source 118 having frequency tuning to provide a third RF energy coupled to an electrode 120 via a third matching network 126. The third matching network 126 may be substantially similar to either matching network 300, 400 depicted in FIGS. 3-4, discussed below, or any other suitable matching network modified in accordance with the teachings provided herein. Similar to embodiments discussed above, one or more second sensors 128 may provide third data corresponding to a third magnitude and a third phase of a third impedance of the third RF energy. The controller 114 may further control a third value of a third variable element of the third matching network 126 based upon the third magnitude and further control a third frequency of the third RF energy source 118 based upon the third phase.

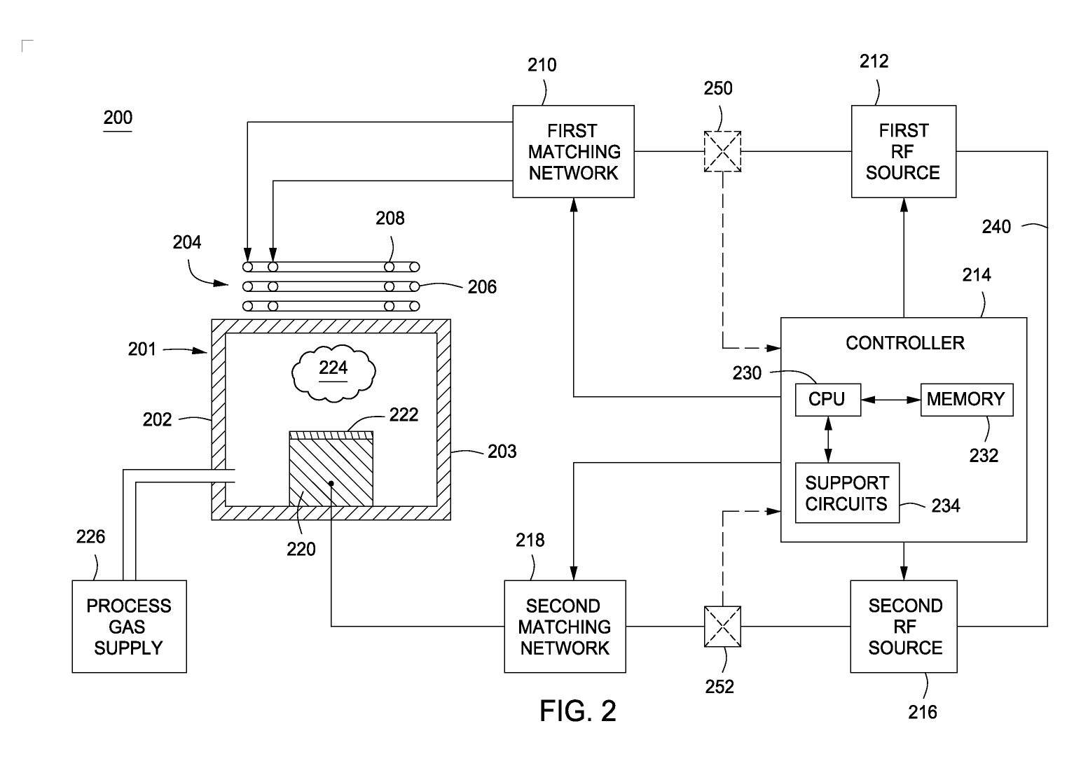

The above embodiments depicted in FIG. 1 are illustrative only and not limiting of the invention. For example, two or more RF energy sources may be coupled to the electrode 120, rather than just one. Also, the electrodes 104, 120 may be located in different positions or may be excluded altogether (such as in embodiments with only a single electrode coupled to one or more RF energy sources). Also, the electrodes may be configured for capacitive (as shown in FIG. 1) or inductive (as shown in FIG. 2) coupling of RF energy into the process chamber.

Some exemplary embodiments of the processing system 100 illustrated in FIG. 1 are depicted in FIG. 2. FIG. 2 is a plasma enhanced semiconductor wafer processing system 200 that, in some embodiments may be used for etching semiconductor wafers 222 (or other substrates and work pieces). Although disclosed embodiments of the invention is described in the context of an etch reactor and process, the invention is applicable to any form of plasma process that uses RF energy during plasma enhanced processes. Non-limiting examples of such reactors include plasma annealing, plasma enhanced chemical vapor deposition, physical vapor deposition, plasma cleaning, and the like. Further, the inventors note that any of the conditions discussed below with the exemplary system 200, for example, such as frequency tuning rates, duty cycles, frequency ranges, or the like may be utilized with any of the embodiments disclosed herein.

The illustrative system 200 includes an etch reactor 201, a process gas supply 226, a controller 214, a first RF energy source 212, a second RF energy source 216, a first matching network 210, and a second matching network 218. Either or both of the first and second RF energy sources 212, 216 may be configured for frequency tuning, as discussed above with respect to FIG. 1. Each RF energy source (212, 216) may be operable in a continuous wave (CW) or pulsed mode, as discussed above.

The etch reactor 201 comprises a vacuum vessel 202 that contains a cathode pedestal 220 (or other support surface) that forms a support for the wafer 222. The roof or lid 203 of the process chamber has at least one antenna assembly 204 proximate the roof 203. In some embodiments, the antenna assembly 204 may include a pair of antennas 206 and 208. Other embodiments of the invention may use one or more antennas or may use and electrode in lieu of an antenna to couple RF energy to a plasma. In this particular illustrative embodiment, the antennas 206 and 208 inductively couple energy to the process gas or gases supplied by the process gas supply 226 to the interior of the vessel 202. The RF energy supplied to the antennas 206 and 208 is inductively coupled to the process gases to form a plasma 224 in a reaction zone above the wafer 222. The reactive gases will etch the materials on the wafer 222.

In some embodiments, the RF energy provided to the antenna assembly 204 ignites the plasma 224 and RF energy coupled to the cathode pedestal 220 controls the ion energy of the plasma 224. As such, RF energy is coupled to both the antenna assembly 204 and the cathode pedestal 220. The first RF energy source 212 (also referred to as a source RF generator) supplies energy to a first matching network 210 that then couples energy to the antenna assembly 204. Similarly, a second RF energy source 216 (also referred to as a bias RF generator) couples energy to a second matching network 218 that couples energy to the cathode pedestal 120. A controller 214 controls the timing of activating and deactivating the RF energy sources 212 and 216 as well as tuning the RF energy sources 212 and 216 and the first and second matching networks 210 and 218. The RF energy coupled to the antenna assembly 204 is known as the source power and the RF energy coupled to the cathode pedestal 220 is known as the bias power. In the embodiments of the invention, either the source power, the bias power, or both can be operated in either a continuous wave (CW) mode or a pulsed mode.

A first indicator device, or sensor, 250 and a second indicator device, or sensor, 252 are used to determine the effectiveness of the ability of the matching networks 210, 218 to match to the plasma 224. In some embodiments, the indicator devices 250 and 252 monitor the magnitude and the phase of the reflected RF energy that is reflected back from plasma in the process chamber through the respective matching networks 210, 218 and towards the respective RF energy sources 212, 215. These devices may be integrated into the matching networks 210, 218, or RF energy sources 212, 215. However, for descriptive purposes, they are shown here as being separate from the matching networks 210, 218.

When data corresponding to reflected RF energy is used as the indicator, the devices 250 and 252 are coupled between the supplies 212, 216 and the matching networks 210 and 218. To produce a signal indicative of reflected energy, the devices 250 and 252 may be a voltage/current sensor coupled to a RF detector such that the match effectiveness indicator signal is a voltage and current that represents the resistance and phase difference of an impedance of an RF energy as discussed above for any of one or more sensors 112, 124, or 128. As discussed, a magnitude of about 50 Ohms and a phase difference of about zero is indicative of a matched situation. The signals produced by the devices 250 and 252 are coupled to the controller 214. In response to an indicator signal, the controller 214 produces a tuning signal (matching network control signal) that is coupled to the matching networks 210, 218. This signal is used to tune the tunable elements (e.g., the variable capacitors and/or inductors) in the matching networks 210, 218. This signal is also used to tune the frequencies of each of the first and second RF energy sources 212, 216. The tuning process strives to minimize or achieve a particular level of the magnitude and phase of the reflected energy as represented in the indicator signal. For example, the magnitude and phase may be driven to a desired value, as discussed above, or the magnitude and phase may be driven to within a desired tolerance of the desired value (such as about 3% or less). The matching networks 210, 218 typically may require up to about 200 milliseconds or greater than 200 milliseconds to adjust the magnitude and the phase of the impedance of the RF energy.

FIG. 3 depicts a schematic diagram of an illustrative matching network 300 used, for example, as the first or second RF matching networks 110, 117 when only a single RF energy source is being coupled through each respectively matching network to the electrode 104. This matching network is merely shown to illustrate aspects of the present invention and other matching networks having other configurations may also be used. Similarly, the matching network 300 may be used for example, as the third matching network 126 as well, or the first matching network 210. The matching network 300 may have a single input 301 and a dual output (i.e., main output 302 and auxiliary output 304). Each output is used to drive one of the two antennas 206, 208 as illustrated in FIG. 2. Alternatively, only the main output 302 may be used for example when driving the electrode 104 as illustrated in FIG. 1. The matching circuit 306 is formed by C₁, C₂ and L₁ and a capacitive power divider 308 is formed by C₃ and C₄. The capacitive divider values are set to establish a particular amount of power to be supplied to each antenna. The values of capacitors C₁ and C₂ are mechanically tuned to adjust the matching of the network 300. Either C₁ or C₂ or both may be tuned to adjust the operation of the network. In lower power systems, the capacitors may be electronically tuned rather than mechanically tuned. Other embodiments of a matching network may have a tunable inductor. The RF energy source may be operated in pulse or CW mode. In some embodiments, the source power that is matched by the network 300 may be at a frequency of about 13.56 MHz and may have a power level of up to about 5000 watts. In some embodiments, the source power that is matched by the network 300 may be at a frequency of about 2 MHz and may have a power level of up to about 11000 watts. In some embodiments, the source power that is matched by the network 300 may be at a frequency of about 162 MHz and may have a power level of up to about 3500 watts. In some embodiments, the source power that is matched by the network 300 may be at a frequency of about 60 MHz and may have a power level of up to about 5000 watts. However, the inventive methods and apparatus described herein may be utilized with any desired combinations of frequency and power level.

FIG. 4 depicts a schematic diagram of one embodiment of an illustrative matching network 400 used, for example, as the third RF matching network 126 or the second RF matching network 218. The matching network 400 may have a single input 401 and a single output 402. The output may be used to drive the electrode 120. The matching network comprises capacitors C₁, C₂, C₃, and inductors L₁ and L₂. The values of capacitors C₂ and C₃ are mechanically tuned to adjust the matching of the network 400. Either C₂ or C₃ or both may be tuned to adjust the operation of the network. In lower power systems, the capacitors may be electronically tuned rather than mechanically tuned. Other embodiments of a matching network may have a tunable inductor. The third RF energy source 118 may be operated in pulse or CW mode. In pulse mode, pulses can occur at a frequency of 100 Hz-100 KHz and a duty cycle of 10-90%. In one embodiment, bias power has a frequency of about 13.56 MHz and has a power level of up to about 5000 watts.

Returning to FIG. 2, the controller 214 comprises a central processing unit (CPU) 230, a memory 232, and support circuits 234. The controller 214 is coupled to various components of the system 200 to facilitate control of the etch process. The controller 214, and the (CPU) 230, memory 232, and support circuits 234, may be substantially similar to the controller 114 discussed above, and may have etching, or other process instructions, stored in the memory 232 as a software routine (such as a process recipe).

FIG. 5 is a representative circuit diagram of one embodiment of a dual frequency matching network 500 having dual L-type match topography, for example, such as the first matching network 110 in embodiments where both the first and second RF energy sources 106, 116 are coupled to the first matching network 110. The dual frequency matching circuit 500 generally includes two matching sub-circuits in which the series elements are fixed and in which the shunt elements provide a variable impedance to ground. The matching circuit 500 includes two inputs that are connected to independent frequency tuned RF energy sources 106, 116 at two separate frequencies and provides a common RF output to the processing chamber 102. The matching network 500 operates to match the impedance of the RF energy sources 106, 116 (typically 500) to that of the processing chamber 102. In one embodiment, the two match sub-circuits are L-type circuits, however, other common match circuit configurations, such as π and T types can be employed.

The matching network 500 generally includes a low frequency (first) tuning sub-circuit 502, a high frequency (second) tuning sub-circuit 504, and a generator isolation sub-circuit 506. First sub-circuit 502 comprises variable capacitor C₁, inductor L₁ and capacitor C₂. The variable capacitor C₁ is shunted across the input terminals 510A, 510B from the first RF energy source (for example, a 2 MHz source) and the inductor L₁ and capacitor C₂ are connected in series from the input terminals 510A and 510B to the common output terminal 512. In one embodiment, variable capacitor C₁ is nominally variable from about 300 pF to about 1500 pF, inductor L₁ is about 30 μH, and capacitor C₂ is about 300 pF.

The generator isolation sub-circuit 506 comprises a ladder topology having three inductors L₃, L₄ and L₅ and three capacitors C₅, C₆ and C₇. This sub-circuit is tuned to block a first RF signal (for example, a 2 MHz signal) provided by the first RF energy source from being coupled to the second RF energy source (for example, a 13 MHz or a 60 MHz source). Inductor L₅ is coupled across input terminals 514A, 514B. The capacitors C₇, C₆ and C₅ are coupled in series from the input terminal 514A to an input 516A to the high-frequency tuning sub-circuit 504. The inductors L₄ and L₃ are respectively coupled in parallel from the junction of capacitors C₇ and C₆ and capacitors C₆ and C₅. In some embodiments, for example where the second RF energy source provides energy at 13.56 MHz, the inductors L₄ and L₅ are about 2 μH and inductor L₃ is about 1 μH. The capacitors C₆ and C₇ are about 400 pF and capacitor L₅ is about 800 pF.

Second sub-circuit 504 comprises capacitor C₃, inductor L₂ and variable capacitor C₄. The variable capacitor C₄ is shunted across input terminals 516A, 516B from the generator isolation sub-circuit 506 and the inductor L₂ and capacitor C₃ are connected in series from the input terminals 516A and 516B to the common output terminal 512. In some embodiments, for example where the second RF energy source provides energy at 13.56 MHz, variable capacitor C₄ is nominally variable from about 400 pF to about 1200 pF, inductor L₂ is about 2.4 pH, and capacitor C₃ is about 67 pF. Embodiments of the matching network 500 that may be modified in accordance with the teachings provided herein and used with embodiments of the processing system 100 are described in U.S. patent application Ser. No. 10/823,371, filed Apr. 12, 2004, by Steven C. Shannon, et al., and entitled, “DUAL FREQUENCY RF MATCH,” which is incorporated by reference herein in its entirety. Other RF energy sources providing RF energy having other frequencies may also be used with the matching network 500. As such, the values described for the matching network 500 are illustrative only and may be varied as needed for use with other RF energy sources having different frequencies.

FIG. 6 depicts a flow chart of a method 600 for tuning a system operating a plasma process in accordance with some embodiments of the present invention. The method 600 is illustratively described below with respect to embodiments of the processing system 100 illustrated in FIG. 1, although other operating systems may also benefit from the present inventive methods. The method 600 begins at 602 by providing a first RF energy at a first frequency to the process chamber 102 via the first RF energy source 106. The RF energy may be used, for example, for at least one of igniting a plasma in a process chamber 102, controlling a density of a plasma in the process chamber 102, controlling a flux of a plasma in the process chamber 102, or the like.

At 604, a first magnitude and a first phase of a first impedance of the first RF energy are determined. As discussed above, the first magnitude may be determined by measuring a first voltage and a first current using the one or more sensors 112 and by calculating the first magnitude based upon the measured voltage and current. The first phase is equal to a first phase difference between the first voltage and the first current.

At 606, a first variable element of the first matching network 110 is tuned to adjust the first magnitude if the first magnitude is not within a desired tolerance of a desired value. For example, and discussed above, the desired value for the first magnitude may be about 50 Ohms and the desired tolerance may be less than about 3%. The first variable element may be for example, any of the capacitors C₁ or C₂ of the matching network 300, as well as any suitable variable elements as discussed above. The tuning algorithm can stop at the desired value because the signal has a positive and negative value relative to the desired value, so the zero, or desired value between the positive and negative can be readily determined. The first variable element of the first matching network 110 may be tuned in incremental steps of a predetermined size. The size of the step may vary depending upon the distance from the desired value (e.g., further points from the desired value may have larger step sizes than from points closer to the desired value).

At 608, the first frequency of the first RF energy source is tuned to adjust the first phase if the first phase difference between the first voltage and the first current is not within a desired tolerance of a desired value. For example, and discussed above, the desired value for the first phase difference may be about zero and the desired tolerance may be less than about 3%. The first frequency may be tuned in incremental steps, as discussed above. For example, in some embodiments, a substrate may be processed in the process chamber 102 using the plasma after the first resistance and the first phase difference are both within the desired tolerance level of the desired value. Otherwise, the first magnitude and/or the first frequency may be adjusted as discussed below until both the first magnitude and first phase are with the desired tolerance of the desired value. The first magnitude and the first phase may be continuously or periodically monitored and adjusted if necessary during processing, between process steps, or as desired.

For example, in an embodiment where at least one of the first magnitude or the first phase of the first impedance is not within a desired tolerance level of the desired value at 606 or 608, the first variable element and/or the first frequency may be adjusted. For example, a first value of the first variable element of the first matching network 110 may be adjusted by a first step to reduce the first magnitude of the first impedance if the first magnitude is not within the desired tolerance level. Similarly, the first frequency of the first RF energy source 106 may be adjusted by a second step to reduce the first phase of the first impedance if the first phase difference is not within the desired tolerance level.

Further at 610, after at least one of adjusting the first value of the first variable element by the first step or adjusting the first frequency by the second step, the first magnitude and the first phase of the first impedance may be iteratively measured and the first value of the first variable element may be tuned until the first magnitude is within a desired tolerance of the desired value and the first frequency of the first RF energy source may be tuned until the first phase is within a desired tolerance of the desired value.

Optionally, at 612, 602 through 610 may be repeated with a second RF energy source, for example either or both of the second RF energy source 116 or the third RF energy source 118. Such measuring and control may be performed simultaneously, sequentially in whole or in part. For example, the first reflected RF energy may be adjusted simultaneously with the adjustment of a second reflected RF energy reflected back to the second RF energy source 116. Alternatively, the first reflected RF energy may be adjusted first, with the adjustment of the second reflected RF energy occurring after the first reflected RF energy is minimized. Alternatively, a predetermined number of one or more iterations to adjust the first reflected RF energy may be performed first, with a predetermined number of one or more iterations to adjust the second reflected RF energy occurring subsequently. The predetermined number may be one, two, or more, or may be based upon reaching a predetermined adjustment in the phase or magnitude rather than a fixed number of iterations. The iterations to adjust the respective first and second reflected RF energies may be alternately performed until the respective phase and magnitude readings for one of the first and second impedances is at the desired value or within the desired tolerance of the desired value. If the other of the first and second reflected RF energy is not at the desired value or within the desired tolerance of the desired value, the adjustment for that impedance may continue until the phase and magnitude is at the desired value or within the desired tolerance of the desired value.

For example, when the third power supply 118 is used, the method includes providing a third RF energy at a third frequency to the process chamber 102 via a third RF energy source 118 coupled to the process chamber 102 via the third matching network 126, measuring a third voltage and a third current, determining the third magnitude and the third phase of the third impedance, tuning a third variable element of the third matching network to adjust the third magnitude if the third magnitude is not within a desired tolerance of the desired value, and tuning the third frequency of the second RF energy source to adjust the third phase if the third phase difference between the third voltage and the third current is not within a desired tolerance of the desired value. Similar to embodiments discussed above, a third value of the third variable element and/or the third frequency may be adjusted stepwise and iteratively until both the third magnitude and the third phase of the third impedance are adjusted to within a desired tolerance level of the desired value.

For example, and in some embodiments, the third RF energy source 118 may be utilized to control a plasma flux proximate the surface of the substrate support 122 or another property of the plasma. Further, once the third magnitude and third phase have been adjusted, the properties of the plasma may change based upon the adjustment. In some embodiments, it may be necessary to measure the prior-adjusted first magnitude and first phase of the prior-adjusted first impedance to ensure that the prior-adjusted first magnitude and first phase remain within the desired tolerance level of the desired value. If the prior-adjusted first magnitude and first phase have fallen outside the desired tolerance level, the method 600 may be repeated to re-adjust the first impedance of the first RF energy.

Similarly, the method steps 602-610 may be repeated for the second RF energy source 116 for example, when coupled to the electrode 104 via the first matching network 110. For example, the method may include providing a second RF energy at a second frequency to the process chamber 102 via the second RF energy source 116 coupled to the process chamber via the first matching network 110, measuring a second voltage and a second current, determining the second magnitude and the second phase of the second impedance, tuning a second variable element of the first matching network to adjust the second magnitude if the second magnitude is not within a desired tolerance of the desired value, and tuning the second frequency of the second RF energy source to adjust the second phase if a second phase difference between the second voltage and the second current is not within a desired tolerance of the desired value. Similar to embodiments discussed above, a second value of the second variable element and/or the second frequency may be adjusted stepwise and iteratively until both the second magnitude and the second phase of the second impedance are reduced to within a desired tolerance level of the desired value.

Further, because adjustment of the second magnitude and second phase of the second impedance may for example, change one or more properties of the plasma, as discussed above, it may be necessary to measure the prior-adjusted first magnitude and first phase of the prior-adjusted first impedance to ensure that the prior-adjusted first magnitude and first phase remain within the desired tolerance level of the desired value. If the prior-adjusted first magnitude and first phase have fallen outside the desired tolerance level, the method 600 may be repeated to re-adjust the first impedance.

Thus, methods and apparatus for radio frequency (RF) plasma processing have been provided. In particular, methods and apparatus for minimizing reflected RF energy during such plasma processing have been disclosed. The inventive methods and apparatus may advantageously provide a stable minimized reflected RF energy state in a plasma process. In some embodiments, the minimized reflected RF energy may be provided by finding a global minimum in reflected RF energy through shared communication between the matching network and the RF energy source. In some embodiments, the minimized reflected RF energy may be provided by adjusting different aspects (e.g., magnitude and phase) of impedance of RF energy provided by the RF energy source. In some embodiments, control of the matching network and the RF energy source may be provided by a common controller to avoid competition between the conventionally independent tuning algorithms of the matching network and the RF energy source. The inventive methods and apparatus advantageously provide reduced tuning time and/or prevent damage due to reflected RF power from impedance mismatch, thus limiting prolonged tool servicing between processes and reducing costs by eliminating the need for more sophisticated match network elements, such phase capacitors, required to achieve tuning using conventional methods.

While the foregoing is directed to embodiments of the present invention, other and further embodiments of the invention may be devised without departing from the basic scope thereof.

1. An apparatus, comprising:
a first RF energy source having frequency tuning to provide a first RF energy;
a first matching network coupled to the first RF energy source;
one or more sensors to provide first data corresponding to a first magnitude and a first phase of a first impedance of the first RF energy; and
a controller to control a first value of a first variable element of the first matching network based upon the first magnitude and to control a first frequency provided by the first RF energy source based upon the first phase.

2. The apparatus of claim 1, wherein the controller further controls the first value of the first variable element to tune the first magnitude to a desired first magnitude value and to control the first frequency to tune the first phase to a desired first phase difference.

3. The apparatus of claim 2, wherein the desired first magnitude value is about 50 Ohms and wherein the desired first phase difference is about zero.

4. The apparatus of claim 1, further comprising:
a process chamber having an electrode to provide RF energy from the first RF energy source into a processing volume of the process chamber, wherein the first RF energy source is coupled to the electrode via the first match network.

5. The apparatus of claim 4, wherein the electrode is at least one of a part of an antenna assembly disposed above a lid of the process chamber, a cathode disposed in a substrate support within the process chamber, or a plate electrode disposed proximate the lid of the process chamber.

6. The apparatus of claim 4, further comprising:
a second RF energy source having frequency tuning to provide a second RF energy; and
a second matching network coupled to second RF energy source, wherein the one or more sensors further provide second data corresponding to a second magnitude and a second phase of a second impedance of the second RF energy, wherein the controller further controls a second value of a second variable element of the second matching network based upon the second magnitude and controls a second frequency provided by the second RF energy source based upon the second phase.

7. The apparatus of claim 6, wherein the controller further controls the second value of the second variable element to tune the second magnitude to a desired second magnitude value and to control the second frequency to tune the second phase to a desired second phase difference.

8. The apparatus of claim 6, wherein the second RF energy source is coupled to the electrode via the second matching network.

9. The apparatus of claim 6, wherein the one or more sensors further comprises:
a first sensor to provide the first data corresponding to the first magnitude and the first phase of the first impedance of the first RF energy; and
a second sensor to provide the second data corresponding to the second magnitude and the second phase of the second impedance of the second RF energy.

10. The apparatus of claim 4, further comprising:
a second RF energy source having frequency tuning to provide a second RF energy coupled to the electrode via the first matching network, wherein the first matching network further comprises a second variable element, wherein the one or more sensors further provides second data corresponding to a second magnitude and a second phase of a second impedance of the second RF energy, wherein the controller further controls a second value of the second variable element of the first matching network based upon the second magnitude and controls a second frequency provided by the second RF energy source based upon the second phase.

11. The apparatus of claim 10, wherein the controller further controls the first value of the first variable element to tune the first magnitude to a desired first magnitude value and the first frequency to tune the first phase to a desired first phase difference and to control the second value of the second variable element to tune the second magnitude to a desired second magnitude value and the second frequency to tune the second phase to a desired second phase difference.

12. The apparatus of claim 10, wherein the desired first and second magnitude values are the same and wherein the desired first and second phase differences are the same.

13. A method for tuning a system operating a plasma process using a first RF energy source capable of frequency tuning and coupled to a process chamber via a first matching network, the method comprising:
providing a first RF energy at a first frequency to the process chamber via the first RF energy source;
measuring a first voltage and a first current;
determining a first magnitude and a first phase of a first impedance of the first RF energy at least partially from the measured first voltage and first current;
tuning a first variable element of the first matching network to adjust the first magnitude if the first magnitude is not within a desired tolerance of a desired value; and
tuning the first frequency of the first RF energy source to adjust the first phase if a first phase difference between the first voltage and the first current is not within a desired tolerance of zero.

14. The method of claim 13, further comprising:
at least one of igniting a plasma in a process chamber, controlling a density of a plasma in the process chamber, or controlling a flux of a plasma in the process chamber using the first RF energy source.

15. The method of claim 13, further comprising:
iteratively measuring the first voltage and the first current to determine the first magnitude and the first phase and tuning the first value of the first variable element until the first magnitude is within a desired tolerance level of about 50 Ohms and tuning the first frequency of the first RF energy source until the first phase difference is within a desired tolerance level of about zero.

16. The method of claim 13, further comprising:
providing a second RF energy at a second frequency to the process chamber via a second RF energy source coupled to the process chamber via a second matching network;
measuring a second voltage and a second current;
determining a second magnitude and a second phase of a second impedance of the second RF energy at least partially from the measured second voltage and second current;
tuning a second variable element of the second matching network to adjust the second magnitude if the second magnitude is not within a desired tolerance of a desired value; and
tuning the second frequency of the second RF energy source to adjust the second phase if a second phase difference between the second voltage and the second current is not within a desired tolerance of zero.

17. The method of claim 16, wherein the first RF energy source is coupled to an electrode disposed proximate a lid of the process chamber and the second RF energy source is coupled to a cathode disposed in a substrate support within the process chamber.

18. The method of claim 16, further comprising:
iteratively measuring the second voltage and the second current to determine the second magnitude and the second phase and tuning the second value of the second variable element until the second magnitude is within a desired tolerance of about 50 Ohms and tuning the second frequency of the second RF energy source until the second phase difference is within a desired tolerance of zero.

19. The method of claim 13, further comprising:
providing a second RF energy at a second frequency to the process chamber via a second RF energy source coupled to the process chamber via the first matching network;
measuring a second voltage and a second current;
determining a second magnitude and a second phase of second impedance of the second RF energy at least partially from the measured second voltage and second current;
tuning a second variable element of the first matching network to adjust the second magnitude if the second magnitude is not within a desired tolerance of a desired value; and
tuning the second frequency of the second RF energy source to adjust the second phase if a second phase difference between the second voltage and the second current is not within a desired tolerance of zero.

20. The method of claim 19, further comprising:
iteratively measuring the second voltage and the second current to determine the second magnitude and the second phase and tuning the second value of the second variable element until the second magnitude is within a desired tolerance of about 50 Ohms and tuning the second frequency of the second RF energy source until the second phase difference is within a desired tolerance of about zero.
